(19) United States
(12) Patent Application Publication
(10) Pub. No.: US 2008/0251910 A1
(43) Pub. Date: Oct. 16, 2008

(54) Fabricating method of semiconductor package and heat-dissipating structure applicable thereto

(75) Inventors: Chih-Wei Chang, Taichung Hsien (TW); Ho-Yi Tsai, Taichung Hsien (TW); Chien-Ping Huang, Taichung (TW); Chun-Ming Liao, Taichung Hsien (TW); Cheng-Hsu Hsiao, Taichung Hsien (TW)

Correspondence Address: Edwards Angell Palmer & Dodge LLP, P.O. Box 55874, Boston, MA, 02205, US

(73) Assignee: Siliconware Precision Industries Co., Ltd., Taichung (TW)

(21) Appl. No.: 12/082,718

(22) Filed: Apr. 11, 2008

(30) Foreign Application Priority Data
Apr. 11, 2007 (TW) 096112654

(51) Int. Cl. H01L 23/36; H01L 21/56

(52) U.S. Cl. 257/712; 438/114; 257/E21.502; 257/E23.101

(57) ABSTRACT

A method for fabricating semiconductor packages is disclosed, including mounting and electrically connecting a semiconductor chip onto a chip carrier; mounting a heat-dissipating structure on the semiconductor chip; placing the heat-dissipating structure into a mold cavity for filling therein a packaging material to form an encapsulant, wherein the heat-dissipating structure has a heat spreader having a size larger than that of the predetermined size of the semiconductor package, a covering layer formed on the, and a plurality of protrusions formed on edges of the covering layer that are free from being corresponding in position to the semiconductor chip, such that the protrusions can abut against a top surface of the mold cavity to prevent the heat spreader from being warped; and finally performing a singulation process according to the predetermined size and removing the encapsulant formed on the covering layer to form the desired semiconductor package. Also, this invention discloses a heat-dissipating structure applicable to the method described above.

### BACKGROUND OF THE INVENTION

1. Field of the Invention

The present invention relates generally to methods of fabricating a semiconductor package, and more particularly, to a method of fabricating a semiconductor package having a heat spreader and the heat-dissipating structure applicable thereto.

2. Description of Related Art

Along with demand for lighter, thinner, smaller and shorter electronic products, semiconductor packages having a semiconductor chip integrating high-density electronic components and electronic circuits have become a mainstream. Such packages in operation produce a large amount of heat, which must be dissipated timely; otherwise, the electric performance of semiconductor chips and product reliability can be seriously affected. On the other hand, in order to protect internal circuits of semiconductor packages from external moisture and dust pollution, the active surface of a semiconductor chip is generally covered by the encapsulants for encapsulating the semiconductor chip. As the encapuslant is generally made of a material with low heat conductivity such as only 0.8 w/m-K, it is difficult for heat generated from active surfaces of semiconductor chips to be efficiently dissipated to the exterior, thereby adversely affecting the electric performance and the lifetime of the semiconductor chips. As a result, heat-dissipating elements have been proposed to be disposed in semiconductor packages for improving heat-dissipating efficiency.

However, when heat-dissipating elements inside semiconductor packages are completely encapsulated by the encapulant, the path for heat dissipation still needs to pass through the encapsulant, and the heat-dissipating efficiency is limited. Therefore, it is necessary to expose surfaces of heat-dissipating elements or semiconductor chips from encapsulants to efficiently dissipate heat of semiconductor packages.

FIG.1 shows a semiconductor package disclosed in U.S. Pat. No. 5,726,079, wherein a heat-dissipating structure 11 is directly attached to the top surface of the semiconductor chip 10, such that the top surface 11a of the heat-dissipating structure 11 is exposed from the encapsulant 12 encapsulating the semiconductor chip 10 and directly in contact with the ambiance. As a result, the heat produced by the semiconductor chip 11 can be directly dissipated to the ambiance without the need of passing through the encapsulant 12.

However, some drawbacks exist in fabrication of the semiconductor package 1. Firstly, when the semiconductor chip 10 with the heat-dissipating structure 11 adhered thereto is disposed inside a mold cavity to perform a molding process for forming the encapsulant 12, the top surface 11a must be abutted against the top wall of the mold cavity, otherwise, overflow of the encapsulant are likely to occur on the top surface 11a of the heat-dissipating structure 11, which can seriously affecting the heat-dissipating efficiency of the heat-dissipating structure 11 and the appearance of the final product. As a result, a deflashing process is needed for removing the overflow of the encapsulant, which not only increases the fabrication time and the fabrication cost, but also leads to product damage. On the other hand, abutting force of a very high magnitude between the heat-dissipating structure 11 and the top wall of the mold cavity may lead to cracking of the semiconductor chip 10, causing a reduction in product yield.

Referring to FIGS. 2A and 2B, in view of the forgoing drawbacks, U.S. Pat. No. 6,458,626 (wherein the assignee is the same as the applicant of the present invention) discloses a semiconductor package, wherein the heat-dissipating structure can be directly attached to the semiconductor chip without causing a damage to the chip or overflow of the encapsulant on the exposed surface of the heat-dissipating structure. In this semiconductor package, a covering layer 25 (such as a gold plated layer) having a poor adhesion with the encapsulant 24 is formed on the exposed surface of heat-dissipating structure 21, and then the heat-dissipating structure 21 is directly attached to a semiconductor chip 20 adhered to a chip carrier 23. Subsequently, a molding process is performed to form an encapsulant 24 completely encapsulating the heat-dissipating structure 21 and the semiconductor chip 20, allowing the encapsulant 24 to cover on the covering layer 25 of the heat-dissipating structure 21 (as shown in FIG. 2A), such that as the depth of the mold cavity used in the molding process is larger than the thickness of the semiconductor chip 20 and the heat-dissipating structure 21, the mold equipment would not be in contact with the heat-dissipating structure 21, thereby eliminating the concerns of the chip being crashed. After that, a singulation process is performed and the encapsulant 24 on the heat-dissipating structure is removed. As the adhesive strength between the covering layer 25 on the heat-dissipating structure 21 and the heat-dissipating structure 21 is larger than that between the covering layer 25 and the encapsulant 24, the encapsulant 24 on the top of the heat-dissipating structure 21 can be easily detached while the covering layer 25 remains on the heat-dissipating structure 21 (as shown in FIG. 2B), such that heat produced by the chip 20 during operation can be dissipated through the heat-dissipating structure 21 and the covering layer 25 without any overflow problem. Prior arts related to this technology include U.S. Pat. Nos. 6,844,622 and 6,444,498.

Referring to FIG. 2C, in the foregoing semiconductor package, the area of the heat-dissipating structure 21, however, is rather large. Therefore, when the heat-dissipating structure 21 is placed in the mold cavity 260 of the packaging mold 26 during the molding process, the room above the top of the heat-dissipating structure 21 for the encapsulant to pass through is much smaller than the space below the heat-dissipating structure 21. As such, the lower mold flow traveling below the heat-dissipating structure 21 is greater than that above the heat-dissipating structure 21, which leads to an imbalance of between the upper mold flow and the lower mold flow the heat-dissipating structure, causing the heat-dissipating structure 21 to suffer from warpage. As a result, the product appearance is degraded, or a delamination may occur at the adhesion interface between the heat-dissipating structure 21 and the semiconductor chip 20. Moreover, electrical connection between the semiconductor chip 20 and the substrate 23 can be adversely affected (for instance, due to cracking of the solder bump for electrically connecting the flip chip with the substrate).

Therefore, it is important to provide a method for fabricating a semiconductor package and the heat-dissipating structure applicable thereto, such that problems such as overflow caused by damages to a semiconductor chip during a molding process, poor adhesion (between the heat-dissipating structure and the semiconductor chip) and poor electrical connection (between the semiconductor chip and the chip carrier) both caused by warpage of the heat-dissipating structure, waste in material, and increased cost may be resolved.

### SUMMARY OF THE INVENTION

According to the above drawbacks, it is therefore an object of the present invention to provide a fabricating method of a semiconductor package and heat-dissipating structure applicable thereto, for preventing warpage of the heat-dissipating structure during the molding process.

It is therefore another object of the present invention to provide a fabricating method of a semiconductor package and heat-dissipating structure applicable thereto, so as to ensure desired adhesion between the heat-dissipating structure and the chip and desired electrical connection between the chip and the chip carrier.

It is a further object of the present invention to provide a fabricating method of a semiconductor package and heat-dissipating structure applicable thereto, so as to avoid waste in materials and reduce production cost.

It is yet another object of the present invention to provide a fabricating method of a semiconductor package and heat-dissipating structure applicable thereto, such that damages to a chip during molding process or the overflow problem can be prevented, so as to enhance the product yield.

In order to attain the above and other objects, the present invention provides a fabrication method of a semiconductor structure, which comprises the steps of: mounting and electrically connecting at least a semiconductor chip with a chip carrier; attaching a heat-dissipating structure to the semiconductor chip, in which the heat-dissipating structure has a heat spreader with a size greater than that of the semiconductor package, a covering layer on the heat spreader, and a plurality of protrusions formed on the covering layer outside an area of the covering layer corresponding in position to the semiconductor chip; forming an encapsulant on the chip carrier for encapsulating the heat-dissipating structure and the semiconductor chip; performing a singulation process according to a predetermined size of the semiconductor package, performing a removal process to remove the encapsulant on the covering layer and the protrusions.

The covering layer may be made of a material with a greater adhesive strength with the heat spreader than with the encapsulant, such as gold or nickel layer, such that during the removal process, the encapsulant on the covering layer and the plurality of protrusions can be easily removed. As a result, heat generated by the semiconductor chip can be dissipated through the heat spreader and the covering layer to the ambiance. Alternatively, the covering layer may be made of a material with a greater adhesive strength with the encapsulant than with the heat spreader, such as a tape, epoxy resin, or organic layer, such that during the removal process, the covering layer, the protrusions on the covering layers and the encapsulant on the covering layer can be all removed at the same time, so as to form a semiconductor package with an exposed heat spreader. The protrusions are formed on the the covering layer by dispensing, either at the middle of each edge, or on the corners of each edge.

In order to attain the same object, a heat-dissipating structure applicable to the semiconductor package by attaching to the surface of a semiconductor chip is also disclosed in the present invention. The heat-dissipating structure comprises a heat spreader with a plane size greater than the semiconductor package; a covering layer formed on the surface of the heat spreader; and a plurality of protrusions formed on edges of the covering layer at the corresponding positions where the semiconductor chip is not to be covered. The foregoing protrusions are formed on the covering layer by dispensing, either at the middle of each edge, or at the corners of each edge.

The fabricating method of the invention and the heat-dissipating structure applicable thereto, mainly involve attaching a heat spreader having a covering layer thereon to a semiconductor chip, wherein the covering layer has a plurality of protrusions formed on the top surface thereof and has a size larger than the predetermined size of the semiconductor package. When filling the packaging material, an upward force is being abutted against the heat spreader as the flow rate of the packaging material below the heat-dissipating structure is greater than that above the heat-dissipating structure, the design of these protrusions are to be abutted against a top surface of the mold cavity of the packaging mold for forming the encapsulant, such that the heat dissipating structure is prevented from deformation due to difference in speed between an upper mold flow traveling above the heat-dissipating structure and a lower mold flow traveling below the heat-dissipating structure, after the upper and lower mold flows enter the mold cavity for forming the encapsulant. This also prevents the problem of delamination between the heat spreader and the semiconductor chip and poor electrical connection between the semiconductor chip and the chip carrier from occurring. Moreover, it is also advantageous to reduce the packaging cost by not increasing the mold cavity. Subsequently, the semiconductor package is removed from the packaging mold and an encapsulant is formed on the surfaces of the heat-dissipating structure and the semiconductor chip, followed by a singulation process on the semiconductor package according to a predetermined size of the semiconductor package and a removal of the protrusions on the covering layers and the encapsulant to finish the fabrication of the semiconductor package incorporated with a heat spreader. In summary, the present invention provides a method to prevent warpage of the heat spreader during molding process, so as to ensure desired adhesion between the heat spreader and the chip and desired electrical connection between the chip and chip carrier, as well as to prevent material waste and reduce production cost. Moreover, problems such as a damage of the semiconductor chip during molding and overflow problem can also be prevented, thereby enhancing the product yield.

### BRIEF DESCRIPTION OF DRAWINGS

FIG. 1 is a schematic view of a semiconductor package with an exposed heat-dissipating structure disclosed by U.S. Pat. No. 5,726,079;

FIGS. 2A to 2C are sectional diagrams of a semiconductor package disclosed by U.S. Pat. No. 6,458,626; and

FIGS. 3A to 3E are schematic diagrams showing a fabricating method of a semiconductor package and the heat-dissipating structure applicable thereto according to a first preferred embodiment of the present invention.

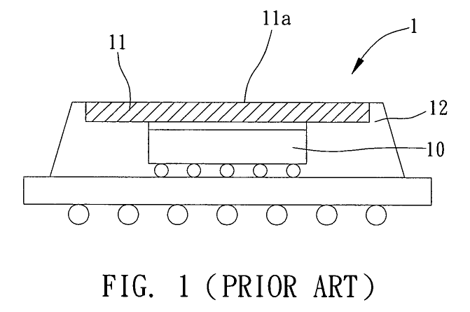

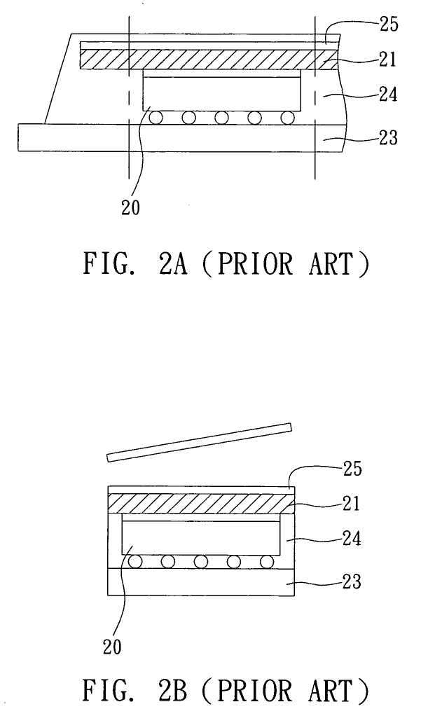

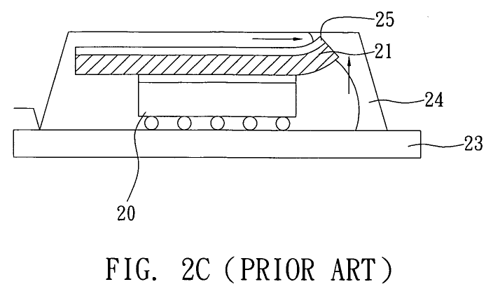

### DETAILED DESCRIPTION OF PREFERRED EMBODIMENTS

The following illustrative embodiments are provided to illustrate the disclosure of the present invention, these and other advantages and effects can be apparent to those skilled in the art after reading the disclosure of this specification.

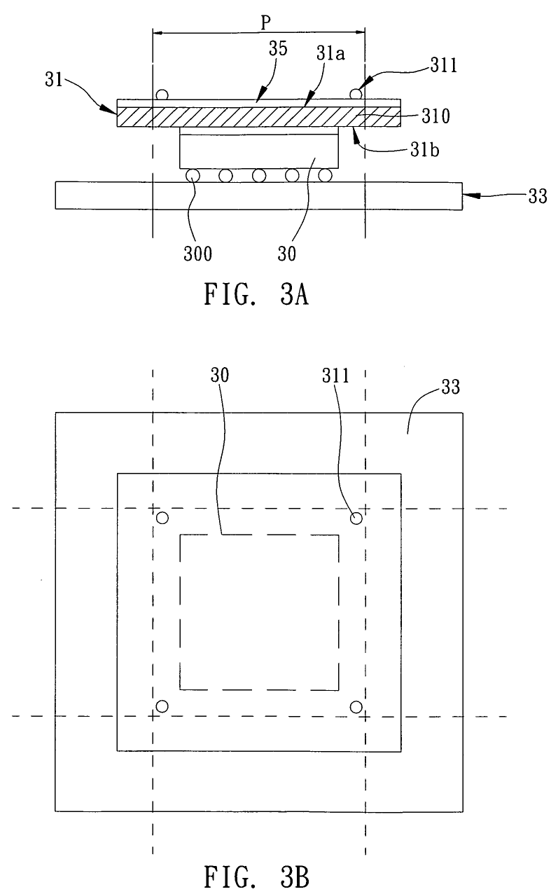

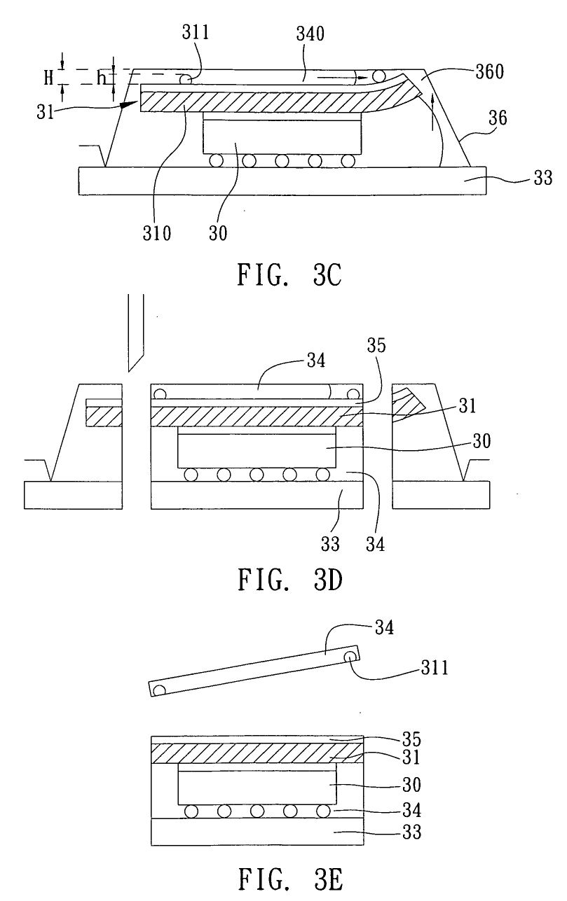

FIGS. 3A to 3E are diagrams showing a fabricating method of a semiconductor package according to a first preferred embodiment of the invention. The fabricating method of the semiconductor package of the invention can be carried out on a single chip carrier or in a batch-type fabrication on a chip module having a plurality of chip carriers.

As shown in FIGS. 3A and 3B, where FIG. 3B is the corresponding top view of FIG. 3A, a semiconductor chip 30 is first attached to and electrically connected with a chip carrier 33, and then a heat-dissipating structure 31 is attached onto the semiconductor chip 30.

The heat-dissipating structure 31 comprises a heat spreader 310 with a plane size greater than a predetermined size P (as indicated by a dashed line) of the semiconductor package, a covering layer 35 formed on the heat spreader 310, and a plurality of protrusions 311 formed on the covering layer 35 outside an area of the covering layer corresponding in position to the semiconductor chip 30 by dispensing. In the present embodiment, the heat spreader 310 has a first surface 31a and an opposing second surface 31b. The covering layer 35 is formed on the first surface 31a, while the semiconductor chip 30 is attached to the second surface 31b. Each protrusion 311 is formed on the covering layer 35 outside an area of the covering layer corresponding in position to the semiconductor chip 30, and can be positioned within the predetermined size P or outside the predetermined size P of the package (within the predetermined size P in this drawing). The heat spreader 310 is attached to the semiconductor chip 30 through its second surface 31b via a conductive adhesive.

In addition, each protrusion 311 is formed on the covering layer 35 by dispensing at the corresponding positions where the semiconductor chip 30 is not to be covered. For example, in the present embodiment, the protrusions 311 are formed on, but not limited to, the corners of the covering layer 35, whereas in the other embodiments, they are formed on the side of the covering layer 35.

The chip carrier 33 is one of the ball grid array (BGA) substrate, land grid array (LGA) substrate, and leadframe. The semiconductor chip 30 is, for example, a flip-chip or a wire bond, which is electrically connected to the chip carrier 33 via a plurality of conductive bumps 300.

The covering layer 35 can be selected from a material with a greater adhesive strength with the heat spreader 310 than that with the encapsulant, such as gold or nickel metal layer. Conversely, a material with a greater adhesive strength with the encapsulant than that with the heat spreader 310, such as tape, epoxy resin, organic layer.

As shown in FIG. 3C, in the molding process, the chip carrier 33 with the semiconductor chip 30 and heat-dissipating structure 31 coupled thereon is placed in a mold cavity 360 of a packaging mold 36, which is then filled with a packaging material 340. The height h of the protrusion 311 of the heat-dissipating structure 31 is smaller than the distance H between top of the heat-dissipating structure 31 and the top of the mold cavity 360, and is around 0.03-0.1 mm, preferably 0.05 mm. In the molding process, when the flow rate of the packaging material 340 below the heat-dissipating structure 31 is greater than that above the heat-dissipating structure 31 with an upper mold flow traveling above the heat spreader 310 of the heat-dissipating structure 31, the problem of warpage of the heat-dissipating structure 31 can be prevented, and this is due to the design of protrusions 311 on the edges of the heat-dissipating structure 31 abutting against the top surface of the mold cavity 360. After the molding process, the package can be taken out from the packaging mold 36.

As shown in FIGS. 3D and 3E, after the packaging material 340 is cured into the encapsulant 34, a singulation process is performed along edges of the chip carrier 33 and the encapsulant 34 according to the predetermined size P.

A removal process is performed subsequently to remove the encapsulant 34 on the covering layer 35, in which the adhesive strength between the material of the covering layer 35 (such as gold or nickel metal layer) and the heat spreader 310 is greater than that between the covering layer 35 and the encapsulant 34, thus the protrusions 311 can be removed along with the encapsulant 34, thereby forming a semiconductor package with the covering layer 35 being exposed. The heat generated from the semiconductor chip 30 can be therefore dissipated through the heat spreader 310 and the covering layer 35 to the ambiance.

In the present embodiment, the material of the covering layer 35 is exemplified by a material with a larger adhesive strength with the heat spreader 310 than with the encapsulant. Thus the covering layer 35 is not removed during the removal process. However, the scope of the present invention is not limited by the embodiment. In the other embodiments, the material of the covering layer 310 can be also selected from a material with a smaller adhesive strength with the heat spreader 310 than with the encapsulant 34, such as tape, epoxy resin, organic layer, such that in the removal process, the covering layer 35, the plurality of protrusions 311 on the covering layer 35 and the encapsulant 34 on the covering layer 35 can be all removed at the same time, so as to form a semiconductor package with a heat spreader 310 directly being exposed.

In addition, the heat-dissipating structure 31 described in the foregoing fabricating method of the present invention comprises: a heat spreader 310 having a plane size larger than the predetermined size P of the semiconductor package; a covering layer 35 formed on the surface of the heat-dissipating fin 310; a plurality of protrusions 311 formed on the the covering layer 35 outside an area of the covering layer corresponding in position to the semiconductor chip 30. The heat spreader 310 has a first surface 31a for the covering layer 35 to be formed thereon and an opposing second surface 31b for the semiconductor chip 30 to be attached thereto.

The fabricating method of the invention and the heat-dissipating structure applicable thereto, mainly involve attaching a heat spreader having a covering layer thereon to a semiconductor chip, wherein a plurality of protrusions are formed on the covering layer has formed on the top surface thereof, and has a size larger than the predetermined size of the semiconductor package. When filling the packaging material, an upward force travels above the heat spreader as the lower mold flow traveling below the heat-dissipating structure is greater than that above the heat-dissipating structure, the design of these protrusions are to be abutted against the mold cavity of the packaging mold to prevent warpage of the heat spreader. This also prevents the problem of delamination between the heat spreader and the semiconductor chip and poor electrical connection between the semiconductor chip and the chip carrier. Moreover, it is also advantageous to reduce the packaging material cost by not increasing the mold cavity. Subsequently, the semiconductor package is removed from the packaging mold and an encapsulant is formed on the surfaces of the heat-dissipating structure and the semiconductor chip, followed by a singulation process on the semiconductor package according to the predetermined size of the semiconductor package and a removal of the protrusions on the covering layers and the encapsulant to finish the fabrication of the semiconductor package incorporated with a heat spreader. In summary, the present invention provides a method to prevent warpage of the heat spreader during molding process, so as to ensure desired adhesion between the heat spreader and the chip and desired electrical connection between the chip and chip carrier, as well as to prevent material waste and reduce production cost. Moreover, problems such as a damage of the semiconductor chip during molding and overflow problem can also be prevented, thereby increasing the product yield.

The invention has been described using exemplary preferred embodiments. However, it is to be understood that the scope of the invention is not limited to the disclosed arrangements. The scope of the claims, therefore, should be accorded the broadest interpretation, so as to encompass all such modifications and similar arrangements.

What is claimed is:

1. A method of fabricating a semiconductor package, comprising the steps of:
mounting and electrically connecting at least a semiconductor chip to a chip carrier;
attaching a heat-dissipating structure to the semiconductor chip, wherein the heat-dissipating structure has a heat spreader of a size greater than that of the semiconductor package, a covering layer formed on the heat spreader, and a plurality of protrusions formed on the covering layer outside an area of the covering layer corresponding in position to the semiconductor chip;
forming an encapsulant on the chip carrier for encapsulating the heat-dissipating structure and the semiconductor chip;
performing a singulation process according to a predetermined size of the semiconductor package; and
removing a portion of the encapsulant formed on the covering layer over the semiconductor package.

2. The method of claim 1, wherein the chip carrier is one of a substrate and a leadframe, and the semiconductor chip is electrically connected to the chip carrier through one of a flip-chip method and a wire bonding method.

3. The method of claim 1, wherein the protrusions are preferably formed on the covering layer at positions outside an area of the covering layer corresponding in position to the semiconductor package and thereby removed subsequent to the singulation process

4. The method of claim 1, wherein the protrusions are formed on the covering layer outside the area of the covering layer corresponding in position to the semiconductor chip and within the area of the covering layer corresponding in position to the semiconductor package, allowing the protrusions to be removed along with the removal of the portion of the encapsulant over the covering layer over the semiconductor package.

5. The method of claim 1, wherein the protrusions are formed on a plurality of corners of the covering layer.

6. The method of claim 1, wherein in the formation of the encapsulant, the protrusions are capable of abutting against a top surface of a mold cavity of a mold for forming the encapsulant, such that the heat dissipating structure is prevented from deformation due to difference in speed between an upper mold flow traveling above the heat-dissipating structure and a lower mold flow traveling below the heat-dissipating structure, after the upper and lower mold flows enter the mold cavity for forming the encapsulant.

7. The method of claim 1, wherein the adhesive strength between the covering layer and the heat spreader is greater than that between the covering layer and the encapsulant such that in the removing step, the encapsulant formed on the covering layer is removed to expose to the ambient the covering layer securely remained on the heat spreader.

8. The method of claim 7, wherein the covering layer is a gold layer.

9. The method of claim 1, wherein the adhesive strength between the covering layer and the encapsulant is greater than that between the covering layer and the heat spreader, such that in the removal process, both the covering layer and the encapsulant formed on the covering layer are simultaneously removed, leaving the heat spreader to be exposed to the ambient.

10. The method of claim 9, wherein the covering layer is one of a tape, an epoxy layer and an organic layer.

11. The method of claim 1, wherein the protrusions are formed on a plurality of edges of a top surface of the covering layer by dispensing.

12. The method of claim 11, wherein the protrusions are made of one of an epoxy material and an organic material.

13. A heat-dissipating structure for use on a semiconductor chip of a semiconductor package, comprising:
a heat spreader having a size larger than a predetermined size of the semiconductor package;
a covering layer formed on the heat spreader; and
a plurality of protrusions formed on the covering layer outside an area of the covering layer corresponding in position to the semiconductor chip.

14. The heat-dissipating structure of claim 13, wherein the covering layer is a metal layer.

15. The heat-dissipating structure of claim 13, wherein the covering layer is one of a tape, an epoxy layer, and an organic layer.

16. The heat-dissipating structure of claim 13, wherein the protrusions are formed on the covering layer by dispensing.

17. The heat-dissipating structure of claim 13, wherein the protrusions are made of one of an epoxy material and an organic material.

18. The heat-dissipating structure of claim 13, wherein the protrusions are formed on a plurality of corners of the covering layer.

19. The heat-dissipating structure of claim 13, wherein the protrusions are formed on the covering layer outside an area of the covering layer corresponding in position to the predetermined size of the semiconductor package.

20. The heat-dissipating structure of claim 13, wherein the protrusions are formed on the covering layer outside the area of the covering layer corresponding in position to the semiconductor package and within the area of the covering layer corresponding in position to the predetermined size of the semiconductor package.
